(19) United States
(12) Patent Application Publication
(10) Pub. No.: US 2018/0267765 A1
(43) Pub. Date: Sep. 20, 2018

(54) JOINTED DISPLAY SCREEN

(71) Applicant: Shenzhen China Star Optoelectronics Technology Co., Ltd., Shenzhen City (CN)

(72) Inventors: Shu Wen, Shenzhen City (CN); Yichien Wen, Shenzhen City (CN); Mingjong Jou, Shenzhen City (CN)

(21) Appl. No.: 15/540,030

(22) PCT Filed: Apr. 11, 2017
(86) PCT No.: PCT/CN2017/080073

§ 371 Date: Jun. 27, 2017

(30) Foreign Application Priority Data
Feb. 28, 2017 (CN) 201710114129.9

(51) Int. Cl. G06F 3/14; H01L 27/32; G09G 3/3225; H01L 51/10

(52) U.S. Cl. CPC G06F 3/1446; H01L 27/3244; G09G 2310/0264; H01L 51/102; G09G 3/3225

(57) ABSTRACT

The present invention provides a jointed display screen, which includes a plurality of OLED display screens (1) that are jointed to each other. Each of the OLED display screens (1) includes a flexible base plate (11) and an OLED panel (13) mounted on the flexible base plate (11). The OLED display screens (1) each include an effective display zone (AA) and a non-display zone (DD) located on an outer circumference of the effective display zone (AA). At a joint site between two adjacent ones of the OLED display screens (1), the non-display zones (DD) of the two adjacent OLED display screens (1) are both bent toward a back of the flexible base plate (11) so as to allow the effective display zones (AA) of the two adjacent OLED display screens (1) to joint to each other in a seamless manner to eliminate thereby eliminating a black strip or a black line occurring at the joint site, making an image displayed continuous, and improving an effect of viewing of the jointed display screen.

### BACKGROUND OF THE INVENTION

### 1. Field of the Invention

The present invention relates to the field of display technology, and more particular to a jointed display screen.

### 2. The Related Arts

In the field of display technology, flat panel display devices, such as liquid crystal display (LCD) and organic light emitting diode (OLED), have gradually taken the place of cathode ray tube (CRT) displays.

The LCDs generally comprise a liquid crystal display panel and a backlight module. The liquid crystal display panel itself does not emit light, light must be provided from the backlight module. Further, the liquid crystal display panel is made up of a color filter (CF) substrate, a thin-film transistor (TFT) array substrate, and a layer of liquid crystal filled between the two substrates. The CF substrate and the TFT substrate both comprise backing plates made of rigid glass so that the liquid crystal display panel, which is generally in the form of a flat panel, is generally not bendable.

Compared to the LCD, the OLED display shows various advantages, such as being thin and light, wide view angle, active light emission, continuous modulation of light color, low cost, fast response speed, low power consumption, low drive voltage, wide range of operation temperature, easy operation of manufacturing, high luminous performance, and being capable of flexible displaying, and is considered a “dream display”. OLED displays can be classified in two categories, which are passive matrix (PM) OLED and active matrix (AM) OLED, namely direct addressing and TFT matrix addressing.

Jointed display screens have been widely used in for example outdoor information media, exhibition halls, squares, venues, and surveillance facility for observation by the public. As shown in FIG. 1, a known jointed LCD display screen 100 that is made of multiple liquid crystal display panels 101 that are jointed to each other. Since the liquid crystal display panels 101 are each composed of a CF substrate and a TFT substrate that comprise backing plates made of rigid glass and since each of the liquid crystal display panels 101 has an outer circumferential frame, a black zone or black strip would be present at a joint site, and this makes the images displayed seemingly discontinuous.

Thus, it is desired to improve the jointed display screen in order to improve the effect of viewing and enhance quality of displaying.

### SUMMARY OF THE INVENTION

An objective of the present invention is to provide a jointed display screen, which comprises a plurality of mutually jointed OLED display screens, each of which comprises a flexible base plate and an OLED panel mounted on the flexible base plate, wherein each of the OLED display screens comprises an effective display zone and a non-display zone located on an outer circumference of the effective display zone.

To achieve the above objectives, the present invention provides a jointed display screen, which comprises a plurality of OLED display screens jointed to each other, wherein each of the OLED display screens comprises a flexible base plate and an OLED panel mounted on the flexible base plate; and the OLED display screens each comprise an effective display zone and a non-display zone located on an outer circumference of the effective display zone;

wherein at a joint site between two adjacent ones of the OLED display screens, the non-display zones of the two adjacent OLED display screens are bent toward a back of the flexible base plate so as to allow the effective display zones of the two adjacent OLED display screens to be jointed to each other in a seamless manner.

The flexible base plate can be made of a material comprising polyimide.

The flexible base plate can be made of a material comprising polyethylene terephthalate.

The non-display zone is provided with a driver of the OLED panel and the driver is made of carbon nanotubes.

The non-display zone is further provided therein with a printed circuit board and the printed circuit board is made of carbon nanotubes.

The effective display zone is provided therein with a drive circuit of the OLED panel and the drive circuit is made of carbon nanotubes.

The drive circuit comprises a plurality of thin-film transistors, and the thin-film transistors each comprise a gate electrode, a first insulation layer set on and covering the gate electrode, an active layer arranged on the first insulation layer, a source electrode and a drain electrode respectively arranged on two sides of the active layer, and a second insulation layer set on and covering the active layer, the source electrode, and the drain electrode.

The thin-film transistors are formed on a buffer layer and the buffer layer is formed on the flexible base plate.

The carbon nanotubes are formed on the flexible base plate through vapor deposition.

The present invention also provides a jointed display screen, which comprises a plurality of OLED display screens jointed to each other, wherein each of the OLED display screens comprises a flexible base plate and an OLED panel mounted on the flexible base plate; and the OLED display screens each comprise an effective display zone and a non-display zone located on an outer circumference of the effective display zone;

wherein at a joint site between two adjacent ones of the OLED display screens, the non-display zones of the two adjacent OLED display screens are bent toward a back of the flexible base plate so as to allow the effective display zones of the two adjacent OLED display screens to be jointed to each other in a seamless manner;

wherein the non-display zone is provided with a driver of the OLED panel and the driver is made of carbon nanotubes; and

wherein the effective display zone is provided therein with a drive circuit of the OLED panel and the drive circuit is made of carbon nanotubes.

The efficacy of the present invention is that the present invention provides a jointed display screen, in which each of OLED display screens that are jointed is provided with a flexible base plate and an OLED panel mounted on the flexible base plate, and at a joint site of every two adjacent ones of the OLED display screens, non-display zones of the two adjacent OLED display screens are bent toward a back side of the flexible base plate so as to allow effective display zones of the two adjacent OLED display screens to joint to each other in a seamless manner thereby eliminating a black strip or a black line occurring at the joint site, making an image displayed continuous, and improving an effect of viewing of the jointed display screen.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a front view illustrating a conventional jointed LCD display screen;

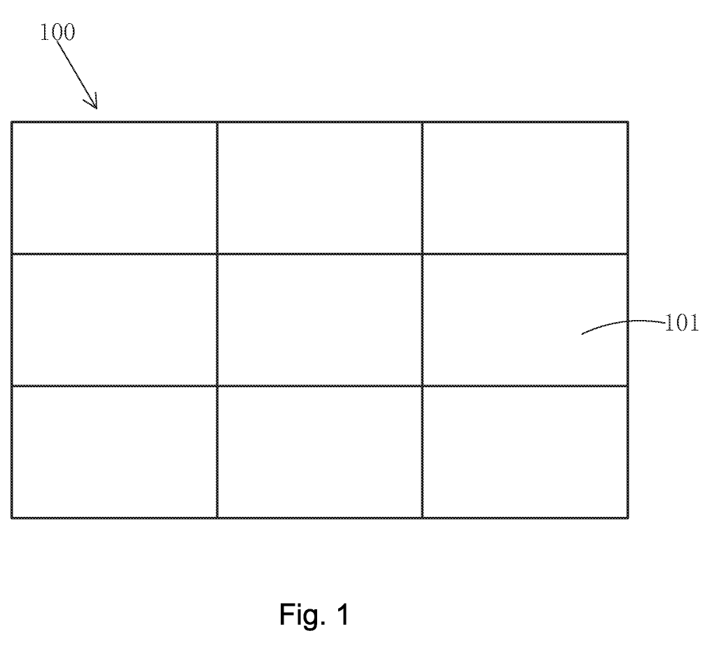

FIG. 2 is a front view illustrating a jointed display screen according to the present invention;

FIG. 3 is a cross-sectional view taken along line B-B of FIG. 2;

FIG. 4 is a cross-sectional view taken along line C-C of FIG. 2; and

FIG. 5 is a cross-sectional view illustrating a thin-film transistor arranged in the jointed display screen according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

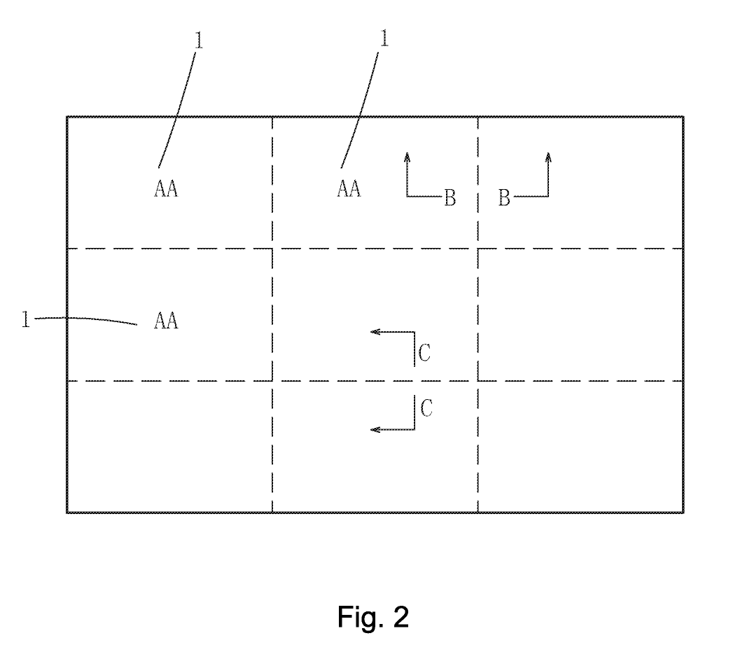

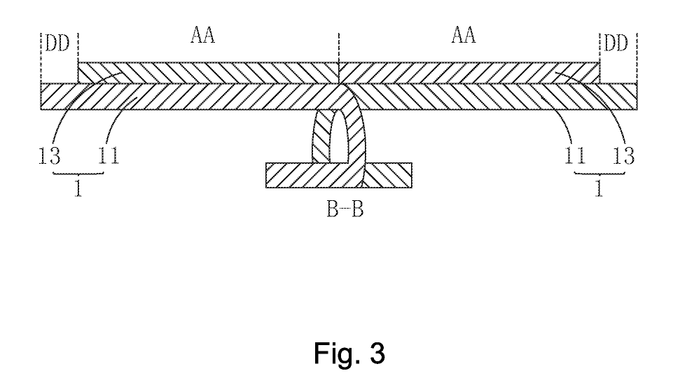

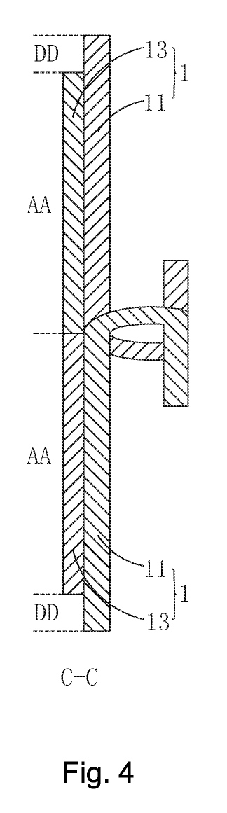

Referring collectively to FIGS. 2, 3, and 4, the present invention provides a jointed display screen, which comprises a plurality of organic light-emitting diode (OLED) display screens 1 that are jointed to each other. Each of the OLED display screens 1 comprises a flexible base plate 11 and an OLED panel 13 mounted on the flexible base plate 11. An OLED display component has the characteristics of self-luminescence and there is no need to provide a backlight module for the OLED panel 13. Thus, the jointed display screen made up of the plurality of OLED display screens 1 is lighter and easier to ship and carry.

The OLED display screens 1 each comprise an effective display zone AA and a non-display zone DD located on an outer circumference of the effective display zone AA. Specifically, the effective display zone AA is arranged to correspond to an area of the OLED panel 13 in which OLED display components are arranged to provide a function of displaying.

Specifically, the flexible base plate 11 is made of a material comprising polyimide (PI) or polyethylene terephthalate (PET).

One side of the flexible base plate 11 that is distant from the OLED panel 13 is referred to as a back of the flexible base plate 11. Due to the material of the flexible base plate 11 shows bendability, at a joint site between two adjacent ones of the OLED display screens 1, the non-display zones DD of the two adjacent OLED display screens 1 are both bent toward the back of the flexible base plate 11 so as to allow the effective display zones AA of the two adjacent OLED display screens 1 to joint to each other in a seamless manner to eliminate any potential black strip or black line generated at the joint site and thus providing a jointed display screen free of black strip or black line and making an image display continuous and improving the effect of viewing of the jointed display screen.

Specifically, the non-display zone DD is provided therein with a driver of the OLED panel 13 and a printed circuit board comprising peripheral circuits of the panel formed thereon. Since the non-display zone DD need to be bent, the driver and the printed circuit board are both made of carbon nanotubes that show excellent flexibility to prevent the driver and the printed circuit board from breaking caused by bending.

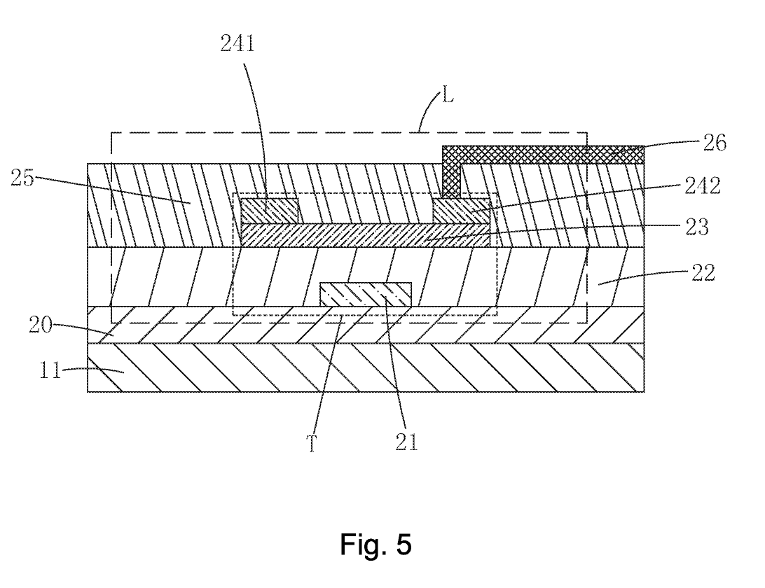

Referring further to FIG. 5, the effective display zone AA is provided therein with a drive circuit L of the OLED panel 13 and to prevent a portion of the drive circuit L of the effective display zone AA that is adjacent to the non-display zone DD from breaking caused by the non-display zone DD being bent toward the back of the flexible base plate 11, the drive circuit L is also made of carbon nanotubes that show excellent flexibility.

The carbon nanotubes are formed on the flexible base plate 11 through vapor deposition.

Further, the drive circuit L comprises a plurality of thin-film transistors T. The thin-film transistors T each comprise a gate electrode 21, a first insulation layer 22 set on and covering the gate electrode 21, an active layer 23 arranged on the first insulation layer 22, a source electrode 241 and a drain electrode 242 respectively arranged on two sides of the active layer 23, and a second insulation layer 25 set on and covering the active layer 23, the source electrode 241, and the drain electrode 242. The thin-film transistors T are formed on a buffer layer 20, and the buffer layer 20 is formed on the flexible base plate 11. The drive circuit L further comprises an anode 26 that is formed on the second insulation layer 25 and is set in engagement with the drain electrode 242 through a via that extends through the second insulation layer 25.

In summary, the present invention provides a jointed display screen, in which each of OLED display screens that are jointed is provided with a flexible base plate and an OLED panel mounted on the flexible base plate, and at a joint site of every two adjacent ones of the OLED display screens, non-display zones of the two adjacent OLED display screens are bent toward a back side of the flexible base plate so as to allow effective display zones of the two adjacent OLED display screens to joint to each other in a seamless manner thereby eliminating a black strip or a black line occurring at the joint site, making an image displayed continuous, and improving an effect of viewing of the jointed display screen.

Based on the description given above, those having ordinary skills in the art may easily contemplate various changes and modifications of he technical solution and the technical ideas of the present invention. All these changes and modifications are considered belonging to the protection scope of the present invention as defined in the appended claims.

What is claimed is:

1. A jointed display screen, comprising a plurality of organic light-emitting diode (OLED) display screens jointed to each other, wherein each of the OLED display screens comprises a flexible base plate and an OLED panel mounted on the flexible base plate; and the OLED display screens each comprise an effective display zone and a non-display zone located on an outer circumference of the effective display zone;
wherein at a joint site between two adjacent ones of the OLED display screens, the non-display zones of the two adjacent OLED display screens are bent toward a back of the flexible base plate so as to allow the effective display zones of the two adjacent OLED display screens to be jointed to each other in a seamless manner.

2. The jointed display screen as claimed in claim 1, wherein the flexible base plate is made of a material comprising polyimide.

3. The jointed display screen as claimed in claim 1, wherein the flexible base plate is made of a material comprising polyethylene terephthalate.

4. The jointed display screen as claimed in claim 1, wherein the non-display zone is provided with a driver of the OLED panel and the driver is made of carbon nanotubes.

5. The jointed display screen as claimed in claim 4, wherein the non-display zone is further provided therein with a printed circuit board and the printed circuit board is made of carbon nanotubes.

6. The jointed display screen as claimed in claim 1, wherein the effective display zone is provided therein with a drive circuit of the OLED panel and the drive circuit is made of carbon nanotubes.

7. The jointed display screen as claimed in claim 6, wherein the drive circuit comprises a plurality of thin-film transistors, and the thin-film transistors each comprise a gate electrode, a first insulation layer set on and covering the gate electrode, an active layer arranged on the first insulation layer, a source electrode and a drain electrode respectively arranged on two sides of the active layer, and a second insulation layer set on and covering the active layer, the source electrode, and the drain electrode.

8. The jointed display screen as claimed in claim 7, wherein the thin-film transistors are formed on a buffer layer and the buffer layer is formed on the flexible base plate.

9. The jointed display screen as claimed in claim 4, wherein the carbon nanotubes are formed on the flexible base plate through vapor deposition.

10. A jointed display screen, comprising a plurality of organic light-emitting diode (OLED) display screens jointed to each other, wherein each of the OLED display screens comprises a flexible base plate and an OLED panel mounted on the flexible base plate; and the OLED display screens each comprise an effective display zone and a non-display zone located on an outer circumference of the effective display zone;
wherein at a joint site between two adjacent ones of the OLED display screens, the non-display zones of the two adjacent OLED display screens are bent toward a back of the flexible base plate so as to allow the effective display zones of the two adjacent OLED display screens to be jointed to each other in a seamless manner;
wherein the non-display zone is provided with a driver of the OLED panel and the driver is made of carbon nanotubes; and
wherein the effective display zone is provided therein with a drive circuit of the OLED panel and the drive circuit is made of carbon nanotubes.

11. The jointed display screen as claimed in claim 10, wherein the flexible base plate is made of a material comprising polyimide.

12. The jointed display screen as claimed in claim 10, wherein the flexible base plate is made of a material comprising polyethylene terephthalate.

13. The jointed display screen as claimed in claim 10, wherein the non-display zone is further provided therein with a printed circuit board and the printed circuit board is made of carbon nanotubes.

14. The jointed display screen as claimed in claim 10, wherein the drive circuit comprises a plurality of thin-film transistors, and the thin-film transistors each comprise a gate electrode, a first insulation layer set on and covering the gate electrode, an active layer arranged on the first insulation layer, a source electrode and a drain electrode respectively arranged on two sides of the active layer, and a second insulation layer set on and covering the active layer, the source electrode, and the drain electrode.

15. The jointed display screen as claimed in claim 14, wherein the thin-film transistors are formed on a buffer layer and the buffer layer is formed on the flexible base plate.

16. The jointed display screen as claimed in claim 10, wherein the carbon nanotubes are formed on the flexible base plate through vapor deposition.
